(19) United States
(12) Patent Application Publication
(10) Pub. No.: US 2025/0176389 A1
(43) Pub. Date: May 29, 2025

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Changqing LI, Hefei (CN); Mengqing YOU, Hefei (CN); Guodong LIU, Hefei (CN); Jinfang ZHANG, Hefei (CN); Lu ZHANG, Kunshan (CN)

(73) Assignees: Hefei Visionox Technology Co., Ltd., Hefei (CN); Visionox Technology Inc., Kunshan (CN)

(21) Appl. No.: 19/036,000

(22) Filed: Jan. 24, 2025

(30) Foreign Application Priority Data
Feb. 28, 2024 (CN) 202410225792.6

(51) Int. Cl. H10K 59/131

(52) U.S. Cl. CPC H10K 59/131

(57) ABSTRACT

The present disclosure discloses a display panel, and a display device. The display panel includes an display area and a non-display area; and the display panel includes: a plurality of first signal lines, a plurality of connection lines, a plurality of fan-out lines, and a plurality of second signal lines, the connection line is connected to the first signal line, and the connection line is located in the display area; at least a part of the fan-out line extends along the first direction and is connected to the connection line, and the fan-out line extends from the non-display area to the display area; the second signal line extends along the first direction.

### CROSS REFERENCE TO RELATED APPLICATION

This application claims priority to the Chinese Patent Application No. 202410225792.6, filed on Feb. 28, 2024, which is incorporated herein by reference in its entirety.

### TECHNICAL FIELD

The present disclosure relates to the field of display technologies, and in particular, to a display panel and a display device.

### BACKGROUND

Organic light emitting displays (OLEDs) as well as flat panel display devices based on technologies such as light-emitting diodes (LEDs) have been widely applied in various consumer electronics such as mobile phones, televisions, laptop computers, and desktop computers due to their advantages such as high image quality, energy efficiency, slim design, and wide applications, making them mainstream in display devices.

However, the process performance of the current OLED display panel needs to be improved.

### SUMMARY

The present disclosure provides a display panel and a display device.

According to an aspect of the present disclosure, a display panel is provided. The display panel includes a display area and a non-display area, and the display panel includes:
a plurality of first signal lines, the first signal line extending along a first direction;
a plurality of connection lines, the connection line being connected to the first signal line, and the connection line being located in the display area;
a plurality of fan-out lines, at least a part of the fan-out line extending along the first direction and being connected to the connection line, and the fan-out line extending from the non-display area to the display area; and
a plurality of second signal lines, the second signal line extending along the first direction;
wherein the first signal line, the second signal line, and the fan-out line are disposed in the same layer and distributed along a second direction intersecting with the first direction.

In some embodiments, the display panel further includes a plurality of power line groups, the power line group being disposed in the same layer as the first signal line, wherein the power line group comprises a first trace and a second trace, the first trace, the second trace, and the first signal line are disposed in the same layer, the display panel further comprises a plurality of pixel circuits, and the first trace and the second trace are respectively connected to the different pixel circuits.

In some embodiments, at least one of the second signal lines or at least one of the fan-out lines is disposed between the first trace and the second trace in the same power line group.

In some embodiments, one of the second signal lines or one of the fan-out lines is disposed between the first trace and the second trace in the same power line group, with the first trace and the second trace being symmetrical with respect to the second signal line or the fan-out line.

In some embodiments, at least one of the second signal lines is disposed between two adjacent ones of the fan-out lines; and
one of the first signal lines is disposed between the adjacent fan-out line and second signal line.

In some embodiments, the plurality of first signal lines form a plurality of first signal line groups, the first signal line group comprises two first signal lines disposed between two adjacent ones of the power line groups, and at least one of the second signal lines or at least one of the fan-out lines is disposed between the two first signal lines in the first signal line group.

In some embodiments, the first signal line groups and the power line groups are alternately arranged along the second direction.

In some embodiments, one of the adjacent fan-out line and second signal line is located between the two first signal lines in the first signal line group, and the other one of the adjacent fan-out line and second signal line is located between the first trace and the second trace in the power line group.

In some embodiments, one first trace or one second trace is disposed between the adjacent fan-out line and second signal line.

In some embodiments, the display panel further comprises a plurality of pixel circuits, the first signal line is a data line configured to transmit a data voltage to the pixel circuit; and the second signal line is a first initialization signal line configured to transmit an initialization voltage to the pixel circuit.

In some embodiments, the display panel further comprises a plurality of pixel circuits, two adjacent pixel circuits of the plurality of pixel circuits are arranged along a row direction and have active layers symmetrical with respect to the second signal line; or two adjacent pixel circuits of the plurality of pixel circuits are arranged along a row direction and have active layers symmetrical with respect to the fan-out line, with the row direction being parallel to the second direction.

In some embodiments, among three pixel circuits arranged sequentially along the row direction, an active layer of a pixel circuit in a middle position and an active layer of a pixel circuit on one side are symmetrical with respect to the second signal line, and the active layer of the pixel circuit in the middle position and an active layer of a pixel circuit on the other side are symmetrical with respect to the fan-out line.

In some embodiments, the display panel further comprises a plurality of light-emitting elements and a plurality of pixel circuits, and the pixel circuit comprises a driving transistor;
the second signal line comprises a first initialization sub-line, wherein the first initialization sub-line is configured to provide an initialization signal to a first electrode of the light-emitting element or a gate of the driving transistor; or
the plurality of second signal lines comprise a plurality of first initialization sub-lines and a plurality of second initialization sub-lines, wherein the first initialization sub-line is configured to provide an initialization signal to a first electrode of the light-emitting element, and the second initialization sub-line is configured to provide an initialization signal to a gate of the driving transistor; or
the plurality of second signal lines comprise a plurality of first initialization sub-lines, a plurality of second initialization sub-lines, and a plurality of third initialization sub-lines, wherein the first initialization sub-line is configured to provide an initialization signal to a first electrode of the light-emitting element, the second initialization sub-line is configured to provide an initialization signal to a gate of the driving transistor, and the third initialization sub-line is configured to provide an initialization signal to a source or a drain of the driving transistor.

In some embodiments, the plurality of second signal lines comprise the plurality of first initialization sub-lines and the plurality of second initialization sub-lines, one first initialization sub-line or one second initialization sub-line is disposed between two adjacent ones of the fan-out lines; or the first initialization sub-line, the second initialization sub-line, and the fan-out line are arranged sequentially along the second direction.

In some embodiments, the plurality of second signal lines comprise the plurality of first initialization sub-lines, the plurality of second initialization sub-lines, and the plurality of third initialization sub-lines, one first initialization sub-line or one second initialization sub-line or one third initialization sub-line is disposed between two adjacent ones of the fan-out lines; or the first initialization sub-line, the second initialization sub-line, the third initialization sub-line, and the fan-out line are arranged sequentially along the second direction.

In some embodiments, the second signal line is a first initialization signal line, the display panel further comprises a substrate and a plurality of second initialization signal lines extending along the second direction, and the second initialization signal line is connected to the second signal line;
the second initialization signal line and the connection line are disposed in the same layer, or a film layer where the second initialization signal line is located is on a side of a film layer where the connection line is located facing the substrate; and
a film layer where the first signal line, the second signal line, and the fan-out line are located is on a side of the film layer where the connection line is located facing or facing away from the substrate.

In some embodiments, the second signal line is a first initialization signal line, the display panel further comprises a substrate, a plurality of scan lines, and a plurality of second initialization signal lines extending along the second direction, and the second initialization signal line is connected to the second signal line; and
the display panel further comprises a first conductive layer and a second conductive layer located on the substrate, the scan line, the second initialization signal line, and the connection line are located in the first conductive layer, and the first signal line, the fan-out line, and the second signal line are located in the second conductive layer.

In some embodiments, the scan line and the connection line are spaced apart from each other; and
along the first direction, the second initialization signal line is located between the scan line and the connection line.

In some embodiments, the second signal line is a first initialization signal line, the display panel further comprises a substrate, a plurality of scan lines, and a plurality of second initialization signal lines extending along the second direction, and the second initialization signal line is connected to the second signal line;
the display panel further comprises a first conductive layer, a second conductive layer, and a third conductive layer that are located on the substrate, the scan line is located in the first conductive layer, and the connection line is located in the second conductive layer; the first signal line, the fan-out line, and the second signal line are located in the third conductive layer; and the second initialization signal line is located in the first conductive layer or the second conductive layer; or
the display panel further comprises a first conductive layer, a second conductive layer, a third conductive layer, and a fourth conductive layer that are located on the substrate, the scan line is located in the first conductive layer; the second initialization signal line is located in the second conductive layer; the connection line is located in the third conductive layer; and the first signal line, the fan-out line, and the second signal line are located in the fourth conductive layer.

According to another aspect of the present disclosure, a display device is provided. The display device includes the display panel described above.

### BRIEF DESCRIPTION OF THE DRAWINGS

In order to more clearly illustrate the technical solutions in the embodiments of the present disclosure, the drawings used in the description of the embodiments will be briefly described below. Obviously, the drawings in the following description are only some embodiments of the present disclosure, and a person skilled in the art can obtain other drawings according to the drawings without any creative work.

FIG. 1 is a schematic top view of a structure of a display panel according to an embodiment of the present disclosure;

FIG. 2 is a sectional view of FIG. 1 taken along line a1-a2;

FIG. 3 is a partial enlarged view of an FA region in FIG. 1;

FIG. 4 is a further partial enlarged view of the FA region in FIG. 1;

FIG. 5 is a further partial enlarged view of the FA region in FIG. 1;

FIG. 6 is a further partial enlarged view of the FA region in FIG. 1;

FIG. 7 is a further partial enlarged view of the FA region in FIG. 1;

FIG. 8 is a further partial enlarged view of the FA region in FIG. 1;

FIG. 9 is a further partial enlarged view of the FA region in FIG. 1;

FIG. 10 is a further partial enlarged view of the FA region in FIG. 1;

FIG. 11 is a further partial enlarged view of the FA region in FIG. 1;

FIG. 12 is a schematic diagram of a structure of a pixel circuit according to an embodiment of the present disclosure;

FIG. 13 is a further partial enlarged view of the FA region in FIG. 1;

FIG. 14 is a schematic diagram of a structure of a further pixel circuit according to an embodiment of the present disclosure;

FIG. 15 is a further partial enlarged view of the FA region in FIG. 1;

FIG. 16 is a schematic diagram of a structure of a further pixel circuit according to an embodiment of the present disclosure;

FIG. 17 is a further partial enlarged view of the FA region in FIG. 1;

FIG. 18 is a sectional view of FIG. 17 taken along line b1-b2;

FIG. 19 is a further sectional view of FIG. 17 taken along line b1-b2;

FIG. 20 is a sectional view of FIG. 17 taken along line c1-c2;

FIG. 21 is a further sectional view of FIG. 17 taken along line c1-c2;

FIG. 22 is a further sectional view of FIG. 17 taken along line c1-c2;

FIG. 23 is a further sectional view of FIG. 17 taken along line c1-c2;

FIG. 24 is a schematic diagram of a structure of a display module according to an embodiment of the present disclosure;

FIG. 25 is a schematic diagram of a structure of an active layer according to an embodiment of the present disclosure; and

FIG. 26 is a schematic diagram of a structure of an active layer according to another embodiment of the present disclosure.

### DETAILED DESCRIPTION OF EMBODIMENTS

In order for a person skilled in the art to better understand the solutions of the present disclosure, the technical solutions in the embodiments of the present disclosure will be clearly and completely described below with reference to the accompanying drawings for the embodiments of the present disclosure. Apparently, the described embodiments are merely some of, rather than all of, the embodiments of the present disclosure. On the basis of the embodiments of the present disclosure, all other embodiments which would have been obtained by those of ordinary skill in the art without involving any inventive effort shall fall within the scope of protection of the present disclosure.

It should be noted that the terms such as “first” and “second” in the description and the claims of the present disclosure and in the aforementioned accompanying drawings are used to distinguish similar objects, and do not necessarily describe a specific order of precedence. It should be understood that the data used in this way can be interchanged where appropriate, so that the embodiments of the present disclosure described herein can be implemented in a sequence other than those illustrated or described herein. In addition, the terms “include” and “have” and any variation thereof are intended to cover a non-exclusive inclusion, for example, a process, method, system, product, or apparatus that includes a series of steps or units is not necessarily limited to those steps or units that are explicitly listed, but may include other steps or units not explicitly listed or inherent to such processes, methods, products or apparatuses.

With the rapid development of display technologies, the demands of users for display panels are increasingly higher, leading to a trend towards narrow-bezel designs for display panels. The display panel includes a plurality of pixel circuits and light-emitting elements, where the pixel circuits are connected to the light-emitting elements to provide driving currents to the light-emitting elements, causing the light-emitting elements to emit light in response to the driving currents. The pixel circuit can be a 2T1C pixel circuit and variations thereof, or a 7T1C pixel circuit and variations thereof. A plurality of data traces are disposed in the display panel, and the data traces are connected to the pixel circuits to supply data voltages for the pixel circuits. In order to transmit data voltages output by a driving chip to the data traces, data fan-out lines and data connection lines are required. The data fan-out lines are connected to corresponding pads of the driving chip, and the data fan-out lines are connected to the data traces through the data connection lines, thereby transmitting the data voltages to the data traces. The routing of the data fan-out lines in the bezel is not conducive to narrow-bezel designs. In the related art, the data fan-out lines are disposed in a display area of the display panel, and the data fan-out lines are connected to the data traces through the data connection lines, so that the number of the data fan-out lines in the bezel area is reduced, thus facilitating the implementation of a narrow bezel.

The display panel further includes signal lines such as reset signal lines. The reset signal lines are connected to the pixel circuits to provide reset signals to the pixel circuits. When there are many traces in the display area, they occupy a lot of conductive layers. In the related art, the reset signal lines, the data fan-out lines, and the data connection lines are located in different conductive layers, resulting in a complex manufacturing process for the display panel and higher production costs of the display panel.

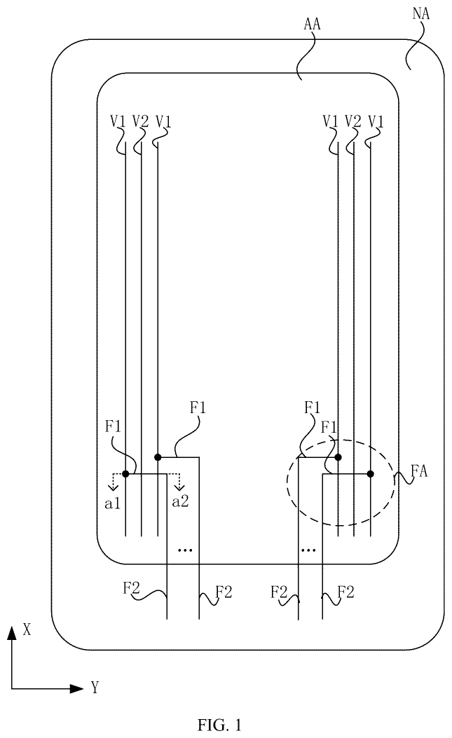

In view of the above problem, embodiments of the present disclosure provides a display panel. FIG. 1 is a schematic top view of a structure of a display panel according to an embodiment of the present disclosure. With reference to FIG. 1, the display panel includes a display area (AA) and a non-display area (NA); and the display panel includes: a plurality of first signal lines V1, a plurality of connection lines F1, a plurality of fan-out lines F2, and a plurality of second signal lines V2, where the first signal line V1 extends along a first direction X;

the connection line F1 is connected to the first signal line V1, and the connection line F1 is located in the display area (AA); at least a part of the fan-out line F2 extends along the first direction X and is connected to the connection line F1, and the fan-out line F2 extends from the non-display area (NA) to the display area (AA); and the second signal line V2 extends along the first direction X.

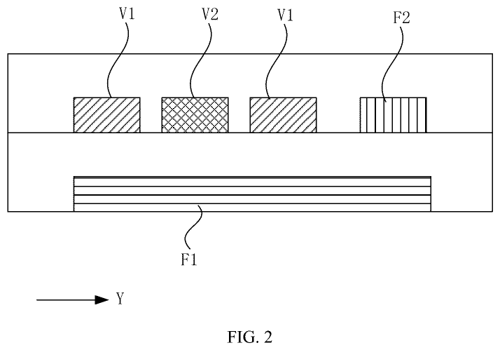

FIG. 2 is a sectional view of FIG. 1 taken along line a1-a2. With reference to FIG. 2, the first signal line V1, the second signal line V2, and the fan-out line F2 are disposed in the same layer and distributed along a second direction Y, with the first direction X intersecting with the second direction Y.

In the display area (AA), the display panel includes pixel circuits and light-emitting elements. The first signal line V1 may be a data line, and the data line may transmit a data voltage to pixel circuits. The first signal line V1 may also be a first initialization signal line, and the first initialization signal line may transmit an initialization voltage to a pixel circuit. For example, it can initialize the first electrode of a light-emitting element, and one or more of the gate, the source, and the drain of a driving transistor. The first signal line V1 may also be other signal lines, for example, a signal line for transmitting a compensation voltage to pixel circuits, or a signal line for transmitting a supply voltage to pixel circuits, which is not limited in this embodiment. The second signal line V2 may be a data line, a first initialization signal line, or other signal lines, for example, a signal line for transmitting a compensation voltage to pixel circuits, or a signal line for transmitting a supply voltage to pixel circuits, which is not limited in this embodiment. For example, the first signal line V1 is of a different type than the second signal line V2, and the first signal line V1 and the second signal line V2 extend along the same direction. The fan-out line F2 may be connected to a pad in the non-display area (NA), which facilitates connection to the driving chip, thereby transmitting the data voltage output from the driving chip through the connection line F1 to the first signal line V1. By disposing the connection line F1 in the display area (AA), traces in the bezel area can be reduced, which facilitates the implementation of a narrow-bezel design.

The connection line F1 may extend along the second direction Y, with the second direction Y intersecting the first direction X, and the connection line F1 may also be an oblique line, which is not limited in this embodiment. A section of the fan-out line F2 that is located in the non-display area (NA) may be an oblique line or may extend along the first direction X, which is not limited in this embodiment.

Specifically, by arranging the first signal line V1, the second signal line V2, and the fan-out line F2 in the same layer, the need to separately arrange the second signal line V2 on an individual film layer is eliminated, so that the number of layers of the film layers in the display panel can be reduced, thereby simplifying the manufacturing process for the display panel. This helps to reduce costs and thus improves the process performance of the display panel. Furthermore, the thickness of the display panel can be reduced, which is conducive to a thin and lightweight design, thereby enhancing the operational performance of the display panel.

The connection line F1 and the fan-out line F2 may be disposed in different layers to avoid cross-shorting between the connection line F1 and fan-out lines corresponding to other connection lines, thereby facilitating the routing of traces. For example, the connection line F1 is connected to the fan-out line F2 through a via hole, and the connection line F1 is connected to the first signal line V1 through a via hole. In some implementations, the connection line F1 may also be disposed in the same layer as the fan-out line F2, which is not limited in this embodiment. FIG. 2 illustrates a situation where the connection line F1 and the fan-out line F2 are disposed in different layers. However, this is not limiting.

It should be noted that FIG. 1 only illustrates a connection relationship of the first signal line V1, the connection line F1, and the fan-out line F2, and shows an extension direction of the second signal line V2, without limiting the arrangement of the first signal line V1, the second signal line V2, the connection line F1, and the fan-out line F2.

According to the technical solution of this embodiment, by disposing the connection line in the display area and extending the fan-out line from the non-display area to the display area, the traces in the bezel of the display panel can be reduced, thus facilitating the implementation of a narrow bezel. By arranging the first signal line, the second signal line, and the fan-out line in the same layer, the need to separately arrange the second signal line on an individual film layer is eliminated, so that the number of layers of the film layers in the display panel can be reduced, thereby simplifying the manufacturing process for the display panel. This helps to reduce costs and thus improves the process performance of the display panel. Furthermore, the thickness of the display panel can be reduced, which is conducive to a thin and lightweight design, thereby enhancing the operational performance of the display panel.

On the basis of the above technical solution, a further illustration of the arrangement of the second signal line V2 and the fan-out line F2 is provided below. However, this is not intended to limit the present application. FIG. 1 does not limit the arrangement of the traces. The following provides an illustration of possible arrangements of the traces.

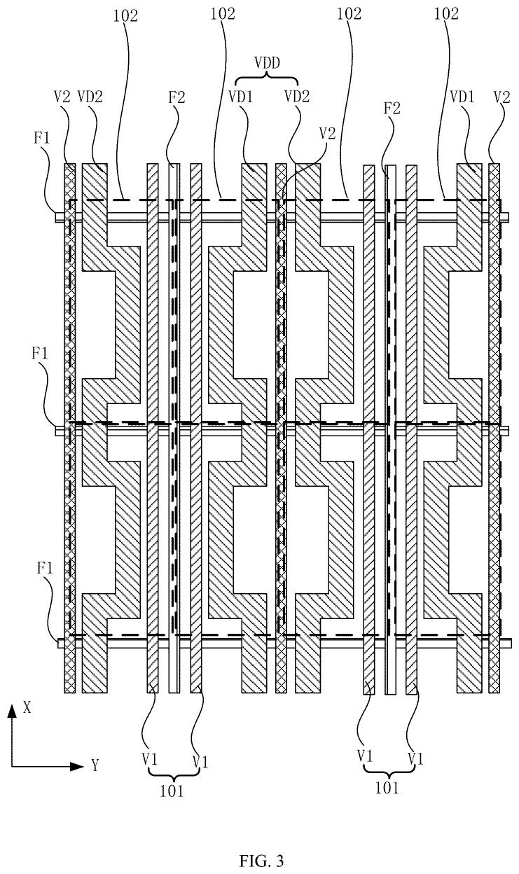

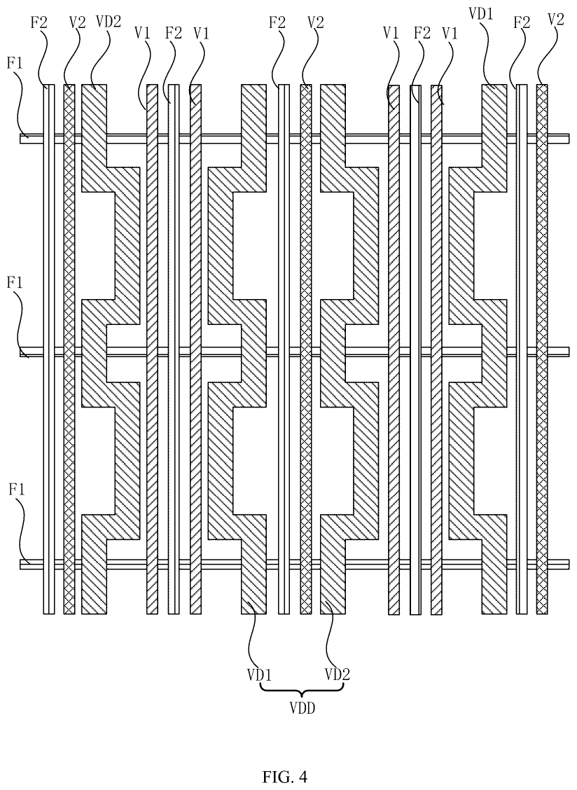

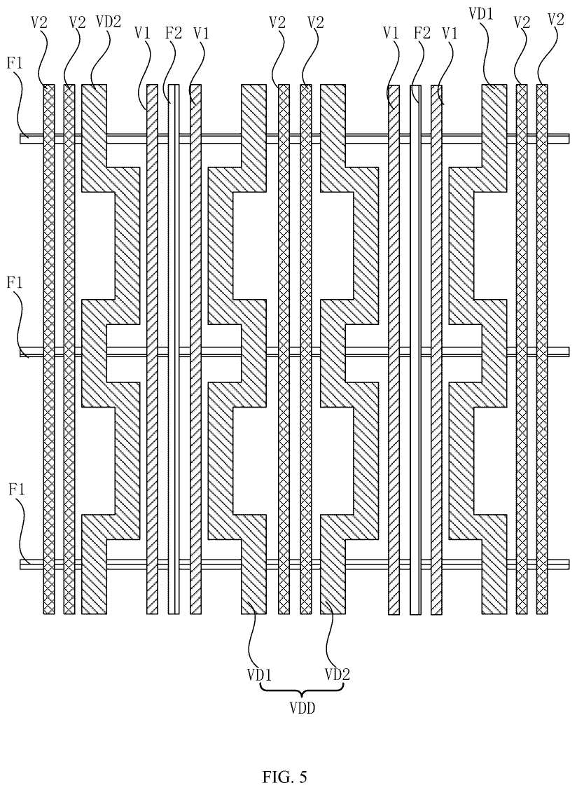

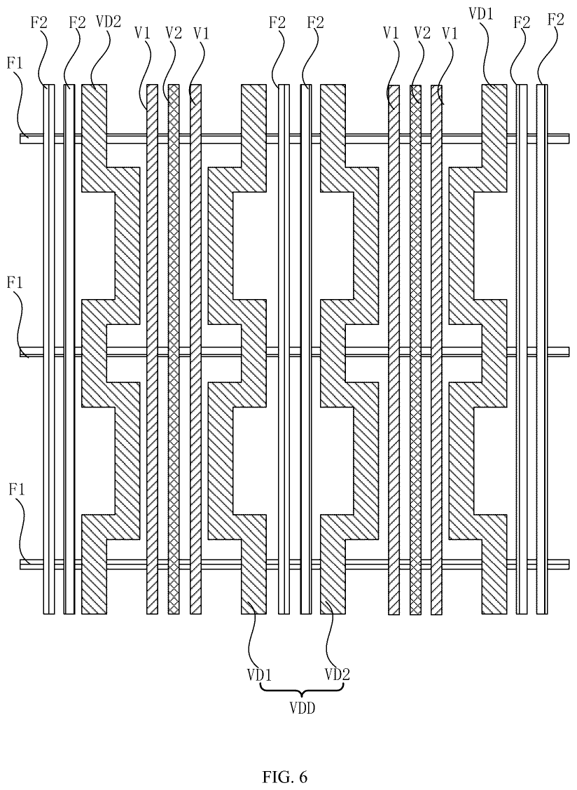

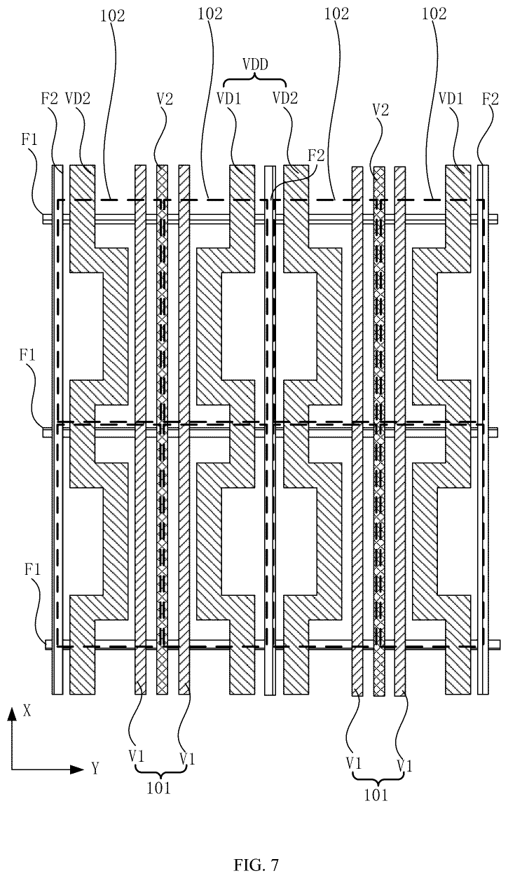

FIG. 3 is a partial enlarged view of an FA region in FIG. 1, FIG. 4 is a further partial enlarged view of the FA region in FIG. 1, FIG. 5 is a further partial enlarged view of the FA region in FIG. 1, FIG. 6 is a further partial enlarged view of the FA region in FIG. 1, and FIG. 7 is a further partial enlarged view of the FA region in FIG. 1. Optionally, with reference to FIGS. 3 to 7, the display panel further includes a plurality of power line groups VDD, the power line group VDD and the first signal line V1 being disposed in the same layer. The power line group VDD can provide a supply voltage to pixel circuits. Disposing the power line group VDD and the first signal line V1 in the same layer can reduce the number of film layers, which helps to simply the manufacturing process and reduce costs, and also helps to achieve a thin and lightweight design of the display panel.

Optionally, with reference to FIGS. 3 to 7, the power line group VDD includes a first trace VD1 and a second trace VD2; in the same power line group VDD, the first trace VD1 is located on a first side of the second trace VD2, where a first side of the first trace VD1 and a second side of the second trace VD2 are provided with the first signal lines V1; the first trace VD1, the second trace VD2, and the first signal line V1 are disposed in the same layer; and the display panel further includes a plurality of pixel circuits, where the first trace VD1 and the second trace VD2 correspond to different pixel circuit columns. The first trace VD1 and the second trace VD2 are respectively connected to the different pixel circuits.

For example, if the first side is the left side and the second side is the right side, the first trace VD1 is located on the left side of the second trace VD2, where the left side of the first trace VD1 and the right side of the second trace VD2 are provided with the first signal lines V1. Alternatively, if the first side is the right side and the second side is the left side, the first trace VD1 is located on the right side of the second trace VD2, where the right side of the first trace VD1 and the left side of the second trace VD2 are provided with the first signal lines V1. The first trace VD1 corresponds to a pixel column on the first side of the first trace VD1, and the second trace VD2 corresponds to a pixel circuit column on the second side of the second trace VD2. FIG. 3 exemplarily depicts 8 pixel circuits, which are arranged in two rows and four columns.

Optionally, the first trace VD1 and the second trace VD2 extend along the first direction X in the form of one or more of a straight line, a curved line, and a polyline. Optionally, the second signal line V2, the fan-out line F2, the first trace VD1, the second trace VD2, and the first signal line V1 are arranged along the second direction Y.

Specifically, by dividing the power line group VDD into a first trace VD1 and a second trace VD2, other signal lines, such as a second signal line V2 and/or a fan-out line F2, can be disposed between the first trace VD1 and the second trace VD2. Compared with the related art, where power line groups corresponding to two adjacent pixel columns are formed as a single metal line, the solution of this embodiment allows for more positions to arrange the fan-out line F2 and the second signal line V2. This facilitates the arrangement of the second signal line V2, the fan-out line F2, the first trace VD1, the second trace VD2, and the first signal line V1 in the same layer, thereby reducing the number of film layers.

Optionally, at least one of the second signal lines V2 and/or at least one of the fan-out lines F2 is disposed between the first trace VD1 and the second trace VD2 in the same power line group VDD. This can facilitate the arrangement of the second signal line V2, the fan-out line F2, and the power line group VDD in the same layer, and also facilitate the arrangement of a plurality of second signal lines V2 and a plurality of fan-out lines F2.

An illustration of the way of arranging traces between the first trace VD1 and the second trace VD2 in the same power line group VDD is provided below by way of example.

In an implementation, optionally, with reference to FIG. 3, a second signal line V2 is disposed between the first trace VD1 and the second trace VD2 in the same power line group VDD. This facilitates moving the second signal line V2 to the film layer where the power line group VDD is located, eliminating the need for a separate layer to dispose the second signal line V2. Furthermore, only the second signal line V2 is disposed between the first trace VD1 and the second trace VD2, which can reduce the process difficulty.

In another implementation, optionally, with reference to FIG. 4, a second signal line V2 and a fan-out line F2 is disposed between the first trace VD1 and the second trace VD2 in the same power line group VDD. In this arrangement, a larger number of second signal lines V2 and fan-out lines F2 can be arranged in the film layer for the power line groups VDD, which can facilitate the arrangement when there are a large number of second signal lines V2. For example, if the second signal line V2 is an initialization signal line, given that each pixel circuit may correspond to a plurality of initialization signal lines and the plurality of initialization signal lines may correspond to different initialization voltages, there will be a large number of second signal lines V2. In this case, the second signal line V2 and fan-out line F2 can be arranged between the first trace VD1 and the second trace VD2.

In a further implementation, optionally, with reference to FIG. 5, two second signal lines V2 are disposed between the first trace VD1 and the second trace VD2 in the same power line group VDD. In this arrangement, a larger number of second signal lines V2 can be arranged in the film layer for the power line groups VDD, which can facilitate the arrangement when there are a large number of second signal lines V2. Furthermore, this is advantageous to ensure the symmetry of the active layers of the pixel circuits. In addition, in some implementations, where the process allows, a plurality of second signal lines V2 can also be disposed between the first trace VD1 and the second trace VD2 in the same power line group VDD, facilitating the arrangement of a larger number of second signal lines V2.

In a further implementation, optionally, with reference to FIG. 6, two fan-out lines F2 are disposed between the first trace VD1 and the second trace VD2 in the same power line group VDD. In this arrangement, a larger number of fan-out lines F2 can be arranged in the film layer for the power line groups VDD, which can facilitate the arrangement when there are a large number of fan-out lines F2. Furthermore, this is advantageous to ensure the symmetry of the active layers of the pixel circuits. In addition, in some implementations, where the process allows, a plurality of fan-out lines F2 can also be disposed between the first trace VD1 and the second trace VD2 in the same power line group VDD, facilitating the arrangement of a larger number of fan-out lines F2.

In a further implementation, optionally, with reference to FIG. 7, a fan-out lines F2 is disposed between the first trace VD1 and the second trace VD2 in the same power line group VDD. This facilitates the arrangement of the second signal line V2, the fan-out line F2, and the power line group VDD in the same film layer, thereby reducing the number of film layers and simplifying the manufacturing process. Furthermore, only the fan-out line F2 is disposed between the first trace VD1 and the second trace VD2, which can reduce the process difficulty.

Optionally, with reference to FIGS. 3 and 7, one second signal line V2 or one fan-out line F2 is disposed between the first trace VD1 and the second trace VD2 in the same power line group VDD, with the first trace VD1 and the second trace VD2 being symmetrical with respect to the second signal line V2 or the fan-out line F2. In this way, only one trace is disposed between the first trace VD1 and the second trace VD2, which can reduce the process difficulty. Furthermore, this allows the first trace VD1 and the second trace VD2 to be symmetrical with respect to the second signal line V2 or the fan-out line F2, so that the coupling capacitance between the first trace VD1 and its corresponding pixel is consistent with the coupling capacitance between the second trace VD2 and its corresponding pixel. As a result, different pixels exhibit uniform luminance at the same grayscale, which is conducive to improving the display uniformity of the display panel and thus enhancing the display effect of the display panel.

In the technical solution of this embodiment, by dividing the power line group VDD into a first trace VD1 and a second trace VD2, a second signal line V2 and/or a fan-out line F2 can be disposed between the first trace VD1 and the second trace VD2, which facilitates the arrangement of the second signal line V2 and the fan-out line F2 in the same layer.

Optionally, with reference to FIGS. 3 and 7, at least one second signal line V2 is disposed between two adjacent ones of the fan-out lines F2. In this arrangement, the arrangement and distribution of the fan-out lines F2 and the second signal lines V2 can be made more uniform, which is conducive to improving the display uniformity of the display panel and thus enhancing the display effect of the display panel.

Optionally, with reference to FIGS. 3 and 7, one of the first signal lines V1 is arranged between either of the adjacent fan-out lines F2 and the second signal line V2.

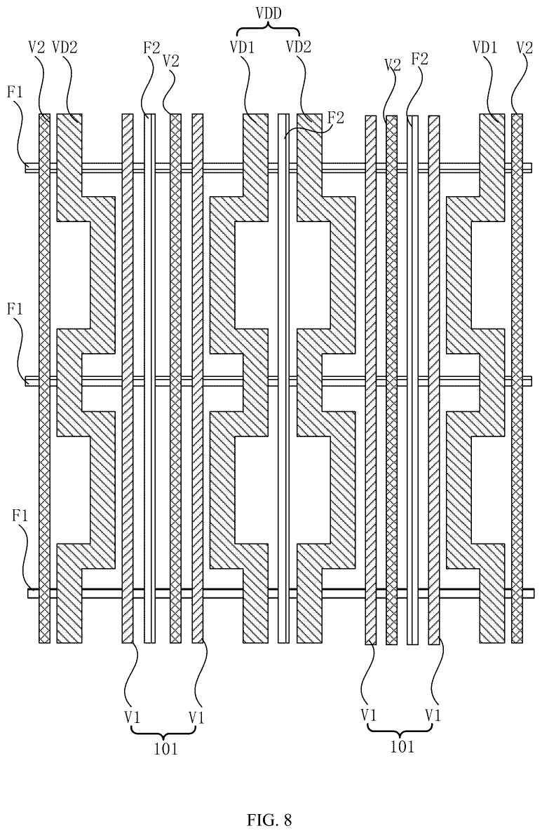

Optionally, FIG. 8 is a further partial enlarged view of the FA region in FIG. 1. With reference to FIGS. 3, 7, and 8, two first signal lines V1 are arranged between two adjacent ones of the power line groups VDD, the two first signal lines V1 forming a first signal line group 101; at least one of the second signal lines V2 and/or at least one of the fan-out lines F2 is disposed between the two first signal lines V1 in the first signal line group 101. This can facilitate the arrangement of the second signal line V2, the fan-out line F2, and the power line group VDD in the same layer, and also facilitate the arrangement of a plurality of second signal lines V2 and a plurality of fan-out lines F2.

Optionally, with reference to FIGS. 3 and 7, when one second signal line V2 or one fan-out line F2 is disposed between the first trace VD1 and the second trace VD2 in the same power line group VDD, and one second signal line V2 or one fan-out line F2 is disposed between the two first signal lines V1 in the first signal line group 101, the fan-out lines F2 and the second signal lines V2 are alternately arranged along the second direction Y. In other words, one second signal line V2 is disposed between two adjacent fan-out lines F2. In this arrangement, the arrangement and distribution of the fan-out lines F2 and the second signal lines V2 can be made more uniform, which is conducive to improving the display uniformity of the display panel and thus enhancing the display effect of the display panel.

An illustration of the way of arranging traces between the two first signal lines V1 in the same first signal line group 101 is provided below by way of example.

In an implementation, optionally, with reference to FIG. 8, two first signal lines V1 are arranged between two adjacent ones of the power line groups VDD, the two first signal lines V1 forming a first signal line group 101; the second signal line V2 and the fan-out line F2 are disposed between the two first signal lines V1 in the first signal line group 101. In this way, a larger number of second signal lines V2 and fan-out lines F2 can be arranged in the film layer for the first signal lines V1, which can facilitate the arrangement when there are a large number of second signal lines V2. For example, if the second signal line V2 is an initialization signal line, given that each pixel circuit may correspond to a plurality of initialization signal lines and the plurality of initialization signal lines may correspond to different initialization voltages, there will be a large number of second signal lines V2. In this case, the second signal line V2 and fan-out line F2 can be arranged between the two first signal lines V1.

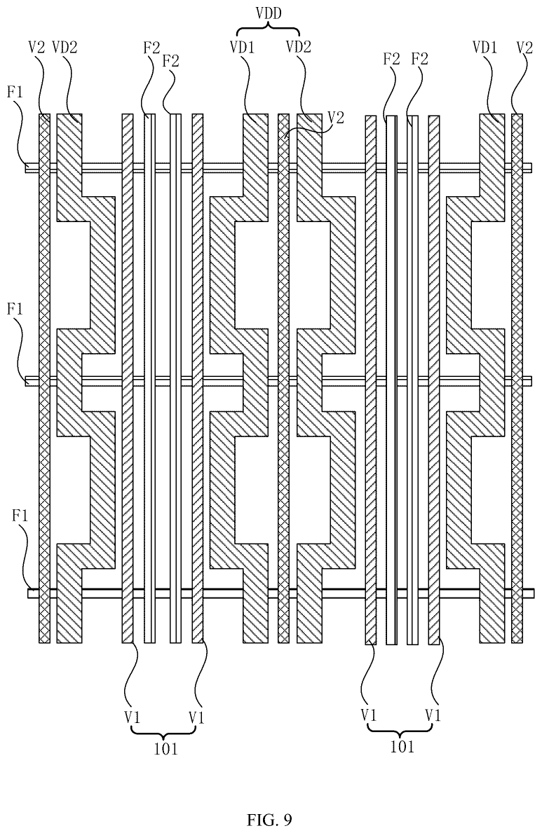

In another implementation, FIG. 9 is a further partial enlarged view of the FA region in FIG. 1. Optionally, with reference to FIG. 9, two fan-out lines F2 are disposed between the two first signal lines V1 in the first signal line group 101. In this arrangement, a larger number of fan-out lines F2 can be arranged in the film layer for the first signal lines V1, which can facilitate the arrangement when there are a large number of fan-out lines F2. Furthermore, this is advantageous to ensure the symmetry of the active layers of the pixel circuits. In addition, in some implementations, where the process allows, a plurality of fan-out lines F2 can also be disposed between the two first signal lines V1 in the same first signal line group 101, facilitating the arrangement of a larger number of fan-out lines F2.

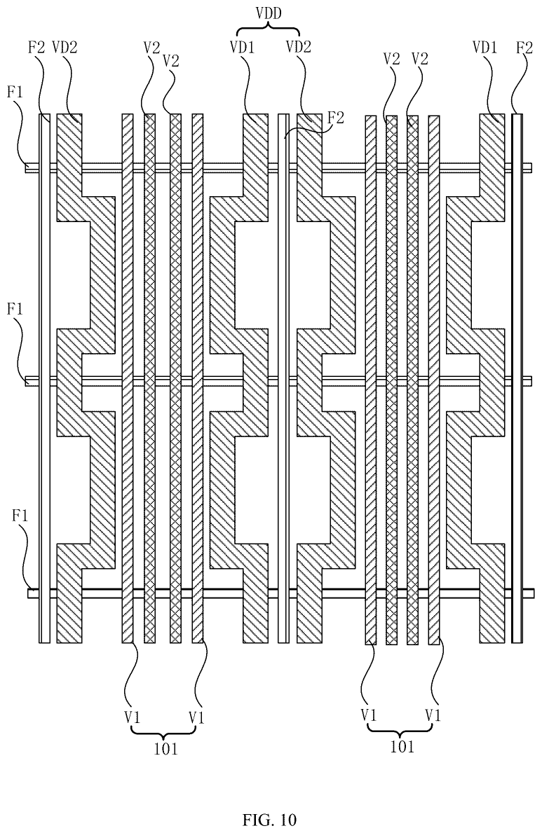

In another implementation, FIG. 10 is a further partial enlarged view of the FA region in FIG. 1. Optionally, with reference to FIG. 10, two second signal lines V2 are disposed between the two first signal lines V1 in the first signal line group 101. In this arrangement, a larger number of second signal lines V2 can be arranged in the film layer for the first signal lines V1, which can facilitate the arrangement when there are a large number of second signal lines V2. Furthermore, this is advantageous to ensure the symmetry of the active layers of the pixel circuits. In addition, in some implementations, where the process allows, a plurality of second signal lines V2 can also be disposed between the two first signal lines V1 in the same first signal line group 101, facilitating the arrangement of a larger number of second signal lines V2.

In another implementation, optionally, with reference to FIG. 7, two first signal lines V1 are arranged between two adjacent ones of the power line groups VDD, the two first signal lines V1 forming a first signal line group 101; and the second signal line V2 is disposed between the two first signal lines V1 in the first signal line group 101. This arrangement facilitates moving the second signal line V2 to the film layer where the first signal line V1 is located, eliminating the need for a separate layer to dispose the second signal line V2. Furthermore, only the second signal line V2 is disposed between the two first signal lines V1 in the first signal line group 101, which can reduce the process difficulty.

In a further implementation, optionally, with reference to FIG. 3, two first signal lines V1 are arranged between two adjacent ones of the power line groups VDD, the two first signal lines V1 forming a first signal line group 101; and the fan-out line F2 is disposed between the two first signal lines V1 in the first signal line group 101. This facilitates the arrangement of the second signal line V2, the fan-out line F2, and the first signal line V1 in the same film layer, thereby reducing the number of film layers and simplifying the manufacturing process. Furthermore, only the fan-out line F2 is disposed between the two first signal lines V1 in the first signal line group 101, which can reduce the process difficulty.

Optionally, with reference to FIGS. 3 and 7, the first signal line groups 101 and the power line groups VDD are alternately arranged along the second direction Y. This arrangement allows each first signal line group 101 to correspond to two pixel columns and each power line group VDD to correspond to two pixel columns, thereby allowing each pixel column to correspond to one first signal line V1 and each pixel column to correspond to one first trace VD1 or one second trace VD2.

Optionally, with reference to FIG. 3 or FIG. 7, one of the adjacent fan-out line F2 and second signal line V2 is located between the two first signal lines V1 in the first signal line group 101, and the other one of the adjacent fan-out line F2 and second signal line V2 is located between the first trace VD1 and the second trace VD2 in the power line group VDD.

Specifically, one trace (either a second signal line V2 or a fan-out line F2) may be disposed between the two first signal lines V1 in the first signal line group 101, which can reduce the process difficulty. Furthermore, this allows the two first signal lines V1 in the first signal line group 101 to be symmetrical with respect to the second signal line V2 or the fan-out line F2, so that in the first signal line group 101, the coupling capacitance between one of the first signal lines V1 and its corresponding pixel is consistent with the coupling capacitance between the other first signal line V1 and its corresponding pixel. As a result, different pixels exhibit uniform luminance at the same grayscale, which is conducive to improving the display uniformity of the display panel and thus enhancing the display effect of the display panel.

The adjacent fan-out line F2 and second signal line V2 are disposed such that one is located between the two first signal lines V1 in the first signal line group 101, and the other is located between the first trace VD1 and the second trace VD2 in the power line group VDD. This allows the fan-out lines F2 and the second signal lines V2 to be alternately arranged, thereby allowing the arrangement and distribution of the fan-out line F2 and the second signal line V2 to be more uniform.

Optionally, with reference to FIG. 3 or FIG. 7, one first trace VD1 or one second trace VD2 is disposed between either of the adjacent fan-out lines F2 and the second signal line V2. This arrangement allows each pixel column to be correspondingly provided with a first trace VD1 or a second trace VD2, enabling each pixel column to receive the supply voltage on the power line group VDD. A part of the first trace VD1 can be reused as a plate electrode of the storage capacitor. A part of the second trace VD2 can be reused as a plate electrode of the storage capacitor.

Optionally, the first signal line V1 is a data line; and the second signal line V2 is a first initialization signal line. In this way, the first signal lines V1 may provide data voltages to corresponding pixel columns, and the second signal lines V2 transmit initialization voltages.

In the technical solution of this embodiment, by arranging the second signal line V2 and/or the fan-out line F2 between the two first signal lines V1, and arranging the second signal line V2 and/or the fan-out line F2 between the first trace VD1 and the second trace VD2, a larger number of second signal lines V2 and fan-out lines F2 can be arranged in the film layer for the first signal lines V1, which can facilitate the arrangement when there are a large number of second signal lines V2.

On the basis of the above technical solution, optionally, with reference to FIG. 3 or FIG. 7, two adjacent pixel circuits 102 of the plurality of pixel circuits are arranged along a row direction and have active layers symmetrical with respect to a second signal line V2; or two adjacent pixel circuits 102 of the plurality of pixel circuits are arranged along a row direction and have active layers symmetrical with respect to a fan-out line F2.

Specifically, the row direction is parallel to the second direction Y. In the row direction, the active layers 200 of the two adjacent pixel circuits 102 are symmetrical with respect to the second signal line V2 (as shown in FIG. 25). In addition, the transistors of two adjacent pixel circuits 102 may also be symmetrical with respect to the second signal line V2, and the capacitors of two adjacent pixel circuits 102 may also be symmetrical with respect to the second signal line V2, thereby further improving the display uniformity of the display panel.

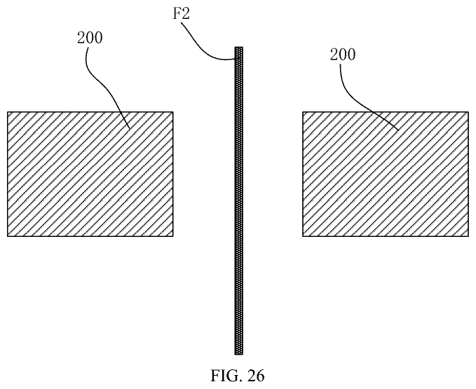

In the row direction, the active layers 200 of two adjacent pixel circuits 102 are symmetrical with respect to the fan-out line F2 (as shown in FIG. 26). In addition, the transistors of two adjacent pixel circuits 102 may also be symmetrical with respect to the fan-out line F2, and the capacitors of two adjacent pixel circuits 102 may also be symmetrical with respect to the fan-out line F2, thereby further improving the display uniformity of the display panel.

Optionally, with reference to FIG. 3 or FIG. 7, among three pixel circuits 102 arranged sequentially along the row direction, an active layer of a pixel circuit 102 in a middle position and an active layer of a pixel circuit 102 on one side are symmetrical with respect to a second signal line V2, and the active layer of the pixel circuit 102 in the middle position and an active layer of a pixel circuit 102 on the other side are symmetrical with respect to a fan-out line F2 (for example, in FIG. 3, an active layer of the second pixel circuit 102 in the first row is symmetrical with respect to a fan-out line F2 with an active layer of a pixel circuit 102 to its left and is symmetrical with respect to a second signal line V2 with an active layer of a pixel circuit 102 to its right).

On the basis of the above technical solutions, an illustration of the arrangement of the second signal lines V2 is provided below in connection with the structure that the second signal lines V2 may contain. However, this is not intended to limit the present application.

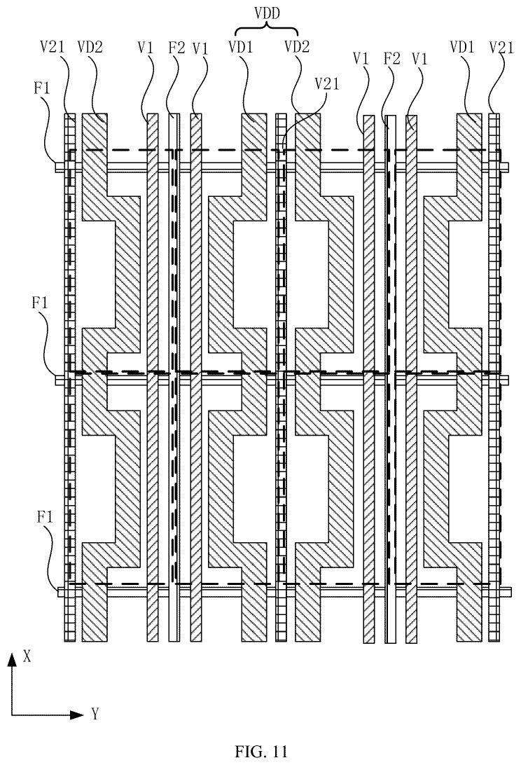

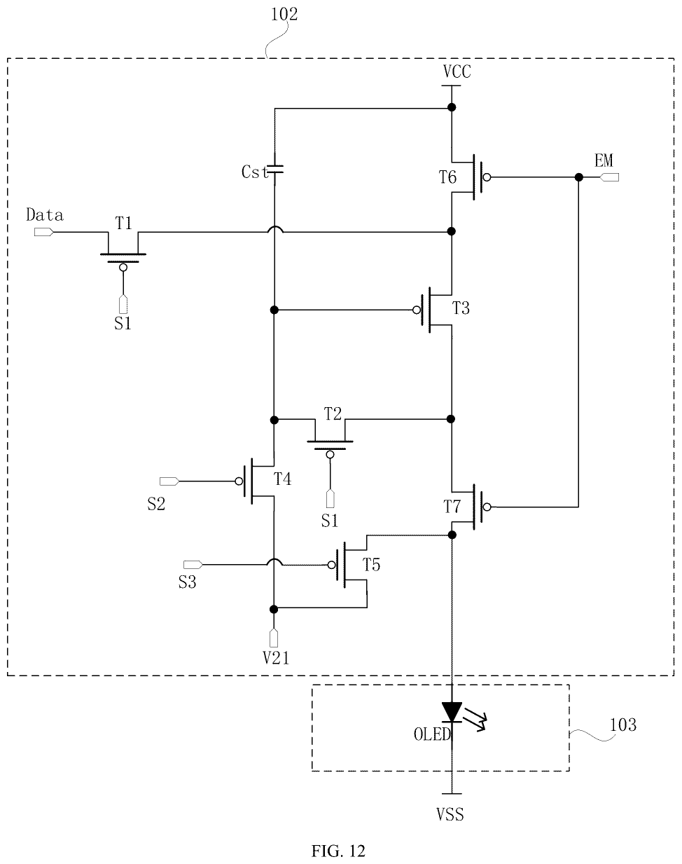

In an implementation, FIG. 11 is a further partial enlarged view of the FA region in FIG. 1, and FIG. 12 is a schematic diagram of a structure of a pixel circuit according to an embodiment of the present disclosure. Optionally, with reference to FIGS. 11 and 12, the second signal line V2 includes a first initialization sub-line V21, where along the second direction Y, the first initialization sub-lines V21 and the fan-out lines F2 are alternately arranged; and the first initialization sub-line V21 is used to provide an initialization signal to a first electrode of a light-emitting element and/or a gate of a driving transistor.

Optionally, as shown in FIG. 12, the pixel circuit 102 is connected to the light-emitting element 103. The pixel circuit 102 includes a data writing transistor T1, a threshold compensation transistor T2, a driving transistor T3, a first initialization transistor T4, a second initialization transistor T5, a first light-emission control transistor T6, a second light-emission control transistor T7, and a storage capacitor Cst. The light-emitting element 103 includes a light-emitting diode OLED. As shown in FIG. 10, the gate of the data writing transistor T1 is connected to a first scan line S1, the first terminal of the data writing transistor T1 is connected to the data line Data, and the second terminal of the data writing transistor T1 is electrically connected to the first terminal of the driving transistor T3. The first terminal of the threshold compensation transistor T2 is electrically connected to the second terminal of the driving transistor T3, the second terminal of the threshold compensation transistor T2 is electrically connected to the gate of the driving transistor T3, and the gate of the threshold compensation transistor T2 is connected to the first scan line S1. The gate of the first initialization transistor T4 is connected to a second scan line S2, the first terminal of the first initialization transistor T4 is connected to the first initialization sub-line V21, and the second terminal of the first initialization transistor T4 is electrically connected to the gate of the driving transistor T3. The gate of the second initialization transistor T5 is connected to a third scan line S3, the first terminal of the second initialization transistor T5 is connected to the first initialization sub-line V21, and the second terminal of the second initialization transistor T5 is electrically connected to the anode of the light-emitting diode OLED (i.e. the first electrode of the light-emitting element 103). The gate of the first light-emission control transistor T6 is connected to a light-emission control line EM, the first terminal of the first light-emission control transistor T6 is connected to a first power supply VCC (i.e., the power line group VDD described above), and the second terminal of the first light-emission control transistor T6 is electrically connected to the first terminal of the driving transistor T3. The gate of the second light-emission control transistor T7 is connected to the light-emission control line EM, the first terminal of the second light-emission control transistor T7 is electrically connected to the second terminal of the driving transistor T3, and the second terminal of the second light-emission control transistor T7 is electrically connected to the anode of the light-emitting diode OLED. The cathode of the light-emitting diode OLED (i.e. a second electrode of the light-emitting element 104) is connected to a second power supply VSS. The storage capacitor Cst is connected between the first power supply VCC and the gate of the driving transistor T3. In this way, the first initialization sub-line V21 may transmit an initialization signal to the gate of the driving transistor T3 through the first initialization transistor T4, or may transmit an initialization signal to the first electrode of the light-emitting element 104 through the second initialization transistor T5. FIG. 12 provides an illustration taking the case where the first initialization sub-line V21 supplies an initialization signal to the first electrode of the light-emitting element and the gate of the driving transistor as an example. However, this is not intended to be limiting.

Specifically, by setting the first initialization sub-lines V21 and the fan-out lines F2 to be alternately arranged, the arrangement and distribution of the first initialization sub-lines V21 and the fan-out lines F2 can be made more uniform. This is conducive to improving the display uniformity of the display panel, thereby enhancing the display effect of the display panel.

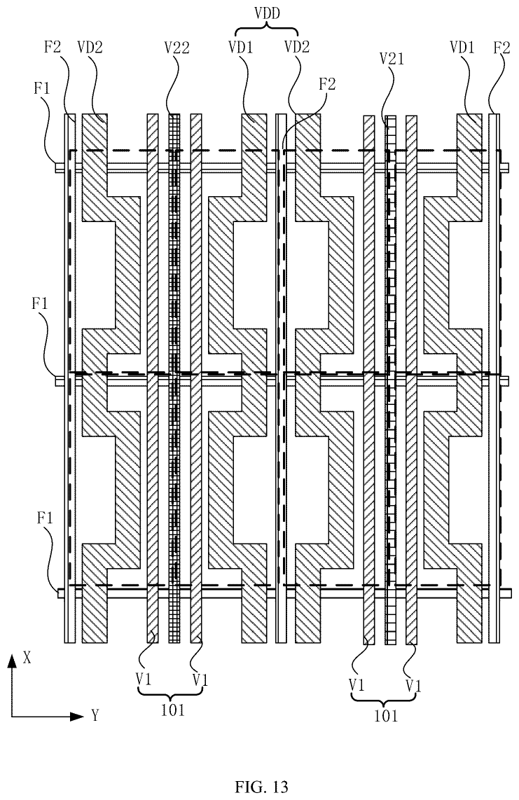

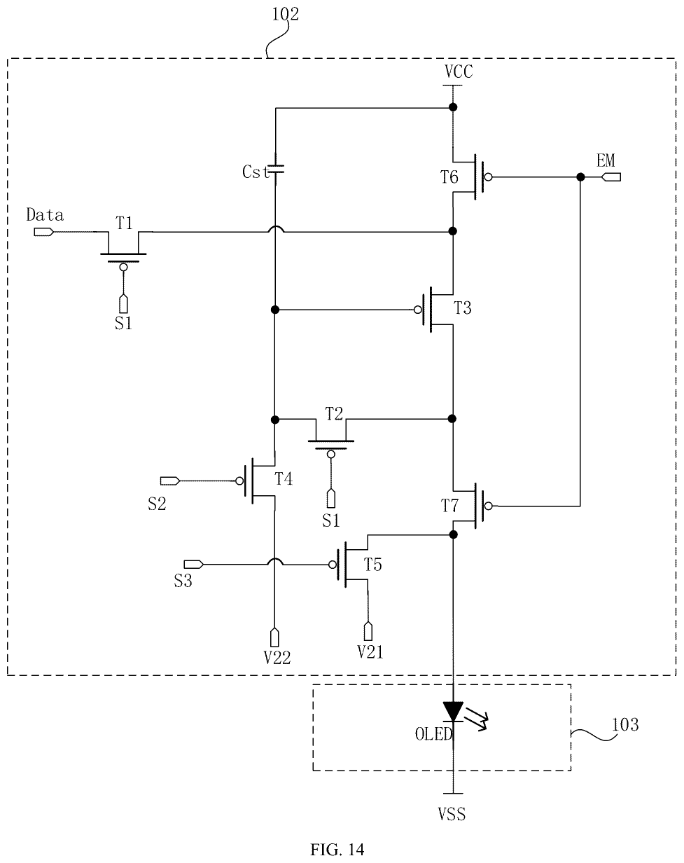

In another implementation, FIG. 13 is a further partial enlarged view of the FA region in FIG. 1, and FIG. 14 is a schematic diagram of a structure of a further pixel circuit according to an embodiment of the present disclosure. Optionally, with reference to FIGS. 13 and 14, the second signal lines V2 includes a plurality of first initialization sub-lines V21 and a plurality of second initialization sub-lines V22; the fan-out line F2 is located between the first trace VD1 and the second trace VD2, the first initialization sub-line V21 or the second initialization sub-line V22 is disposed between the two first signal lines V1 in the first signal line group 101, and the first initialization sub-lines V21 and the second initialization sub-lines V22 are alternately arranged along the second direction Y; and optionally, the first initialization sub-line V21 is used to provide an initialization signal to a first electrode of a light-emitting element 103, and the second initialization sub-line V22 is used to provide an initialization signal to a gate of a driving transistor. In FIG. 13, one first initialization sub-line V21 or one second initialization sub-line V22 is disposed between two adjacent fan-out lines F2.

The difference between FIG. 14 and FIG. 12 lies in that, in FIG. 14, the first terminal of the first initialization transistor T4 is connected to the second initialization sub-line V22, while the first terminal of the second initialization transistor T5 is connected to the first initialization sub-line V21. In this way, the second initialization sub-line V22 may transmit an initialization signal to the gate of the driving transistor T3 through the first initialization transistor T4, and the first initialization sub-line V21 may transmit an initialization signal to the first electrode of the light-emitting element 103 through the second initialization transistor T5.

In another implementation, the first initialization sub-line V21, the second initialization sub-line V22, and the fan-out line F2 are arranged sequentially along the second direction Y. In this way, an alternating arrangement between the second signal lines V2 and the fan-out lines F2 can be achieved, thereby facilitating the uniformity of the arrangement and enhancing the display uniformity of the display panel.

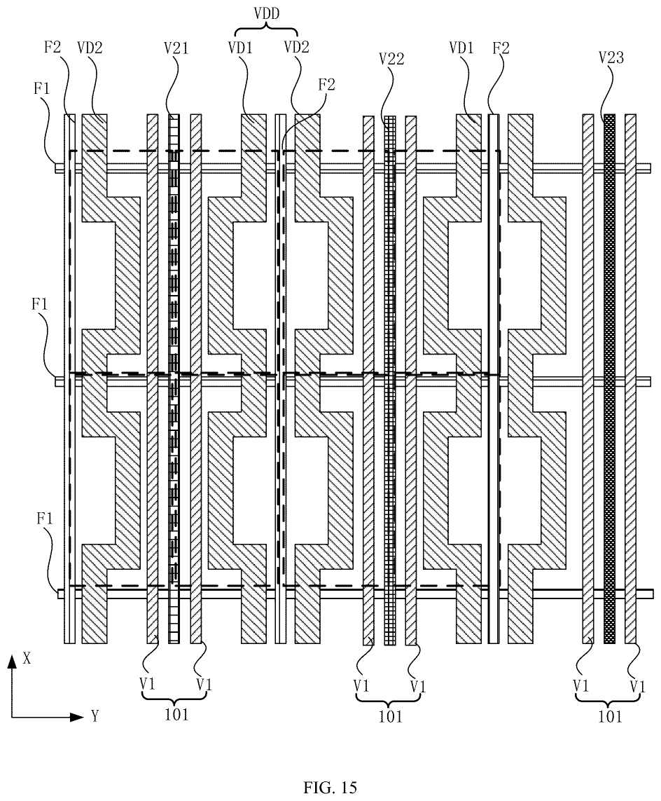

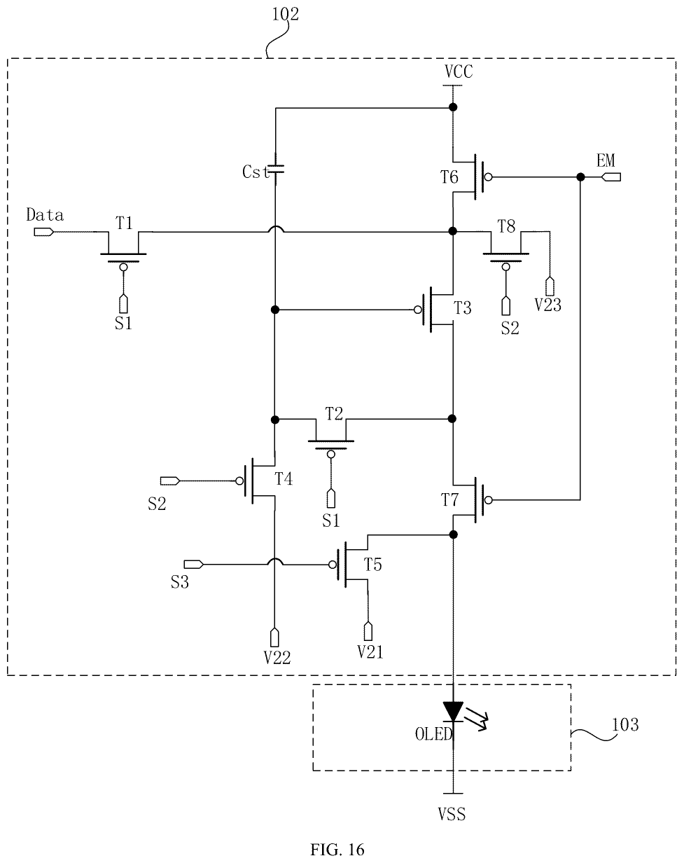

In a further implementation, FIG. 15 is a further partial enlarged view of the FA region in FIG. 1, and FIG. 16 is a schematic diagram of a structure of a further pixel circuit according to an embodiment of the present disclosure. Optionally, with reference to FIGS. 15 and 16, the second signal lines V2 includes a plurality of first initialization sub-lines V21, a plurality of second initialization sub-lines V22, and a plurality of third initialization sub-lines V23; the fan-out line F2 is located between the first trace VD1 and the second trace VD2, the first initialization sub-line V21, the second initialization sub-line V22, or the third initialization sub-line V23 is disposed between the two first signal lines V1 in the first signal line group 101, and the first initialization sub-line V21, the second initialization sub-line V22, and the third initialization sub-line V23 are alternately arranged along the second direction Y; and the first initialization sub-line V21 is used to provide an initialization signal to a first electrode of a light-emitting element 103, the second initialization sub-line V22 is used to provide an initialization signal to a gate of a driving transistor, and the third initialization sub-line V23 is used to provide an initialization signal to a source and/or a drain of the driving transistor. In FIG. 15, one first initialization sub-line V21 or one second initialization sub-line V22 or one third initialization sub-line V23 is disposed between two adjacent fan-out lines F2.

The difference between FIG. 16 and FIG. 14 lies in that, in FIG. 16, the pixel circuit further includes a third initialization transistor T8, where the gate of the third initialization transistor T8 is connected to the second scan line S2, the first terminal of the third initialization transistor T8 is connected to the third initialization sub-line V23, and the second terminal of the third initialization transistor T8 is electrically connected to the first terminal of the driving transistor T3. In some other implementations, the second terminal of the third initialization transistor T8 may also be electrically connected to the second terminal of the driving transistor T3. FIG. 16 illustrates the situation where the second terminal of the third initialization transistor T8 is electrically connected to the first terminal of the driving transistor T3. However, this is not intended to be limiting. One of the first and second terminals of the driving transistor T3 is the source and the other is the drain.

Specifically, by setting the fan-out line F2 to be located between the first trace VD1 and the second trace VD2, and disposing the first initialization sub-line V21, the second initialization sub-line V22, or the third initialization sub-line V23 between the two first signal lines V1 in the first signal line group 101, more positions are made available for the arrangement of the fan-out lines F2, which facilitates better implementation of a narrow bezel.

In another implementation, the first initialization sub-line V21, the second initialization sub-line V22, the third initialization sub-line V33, and the fan-out line F2 are arranged sequentially along the second direction Y. In this way, an alternating arrangement between the second signal lines V2 and the fan-out lines F2 can be achieved, thereby facilitating the uniformity of the arrangement and enhancing the display uniformity of the display panel.

It should be noted that, in some other embodiments, the second signal lines V2 can be used to form a mesh structure with other signal lines that transmit the same signal. In this case, the second signal lines V2 may not be connected to the pixel circuits directly. Instead, the signal lines that transmit the same signal as the second signal lines V2 are connected to the pixel circuits to transmit the initialization signal to the pixel circuits.

The technical solution of this embodiment ensures that the second signal lines V2 and the fan-out lines F2 are arranged sequentially in the case where the second signal lines V2 contain different numbers of initialization sub-lines. This contributes to achieving uniform arrangement and enhancing the display uniformity of the display panel.

On the basis of the above technical solutions, an illustration of the film layers in which various metal lines are located is provided below. However, this is not intended to limit the present application.

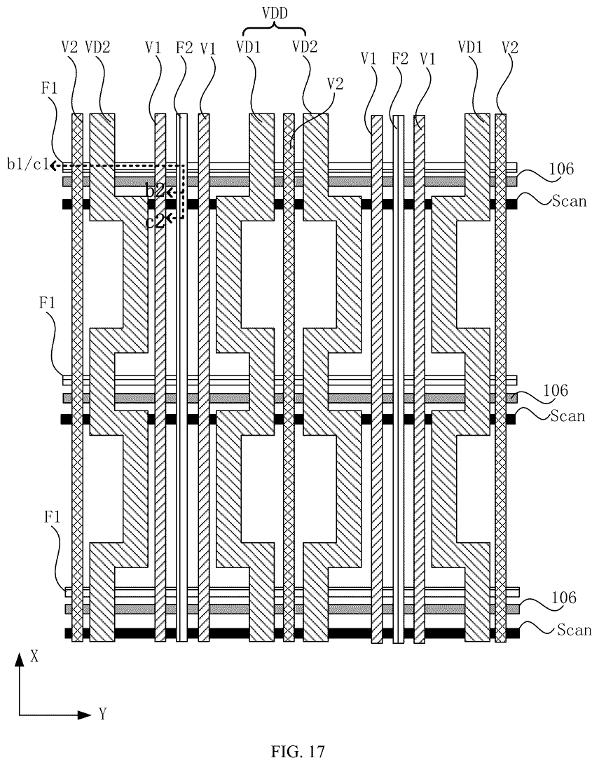

FIG. 17 is a further partial enlarged view of the FA region in FIG. 1. Optionally, with reference to FIG. 17, the display panel further includes a substrate 105 and a plurality of second initialization signal lines 106 extending along the second direction Y, the second initialization signal line 106 being connected to the second signal line V2.

In an implementation, the second initialization signal lines 106 are connected to the pixel circuits through via holes, and the second signal lines V2 are connected to the second initialization signal lines 106 through via holes.

Specifically, the extension direction of the second initialization signal line 106 intersects that of the second signal line V2, so that the second signal lines V2 and the second initialization signal lines 106 form a mesh structure. This can ensure that the voltage drop on each second signal line V2 tends to be consistent, which helps to enhance the display uniformity of the display panel.

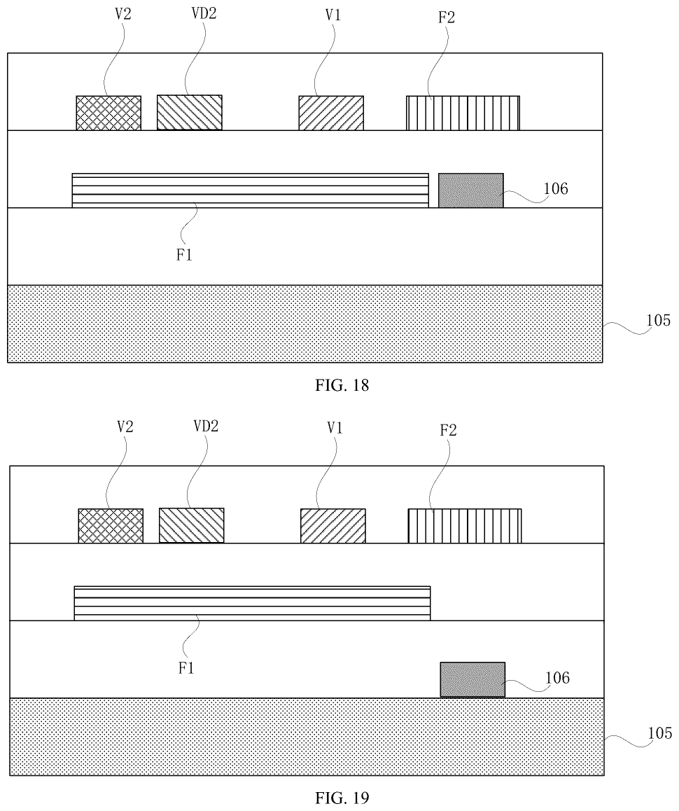

In an implementation, FIG. 18 is a sectional view of FIG. 17 taken along line b1-b2. Optionally, with reference to FIG. 18, the second initialization signal line 106 is disposed in the same layer as the connection line F1. In this way, there is no need to provide a separate film layer for the second initialization signal lines 106 or the connection lines F1, which helps to reduce the number of film layers and simplify the manufacturing process, thereby reducing costs.

In another implementation, optionally, FIG. 19 is a further sectional view of FIG. 17 taken along line b1-b2. With reference to FIG. 19, the film layer where the second initialization signal line 106 is located is on a side of the film layer where the connection line F1 is located that is facing the substrate 105. In this arrangement, the connection line F1 can be arranged separately in an individual film layer, which allows the material of the connection line F1 to differ from that of the second initialization signal line 106. For example, the resistivity of the material of the connection line F1 can be set to be lower than that of the material of the second initialization signal line 106. This helps to reduce the value of resistance of the connection line F1, thereby reducing the voltage drop on the connection line F1. As a result, the voltage loss during transmission on the connection lines F1 is reduced, thereby enhancing the accuracy of signal transmission.

Optionally, a film layer where the first signal line V1, the second signal line V2, and the fan-out line F2 is located is on a side of the film layer where the connection line F1 is located that is facing or facing away from the substrate 105.

Specifically, when the film layer where the first signal line V1, the second signal line V2, and the fan-out line F2 are located is on a side of the film layer where the connection line F1 is located that is facing away from the substrate 105, the first signal line V1 and the second signal line V2 are farther from the substrate 105, which can reduce the coupling capacitance of the first signal line V1 and the second signal line V2 with other film layers on the substrate 105, so that the signals transmitted on the first signal line V1 and the second signal line V2 are more accurate. When the film layer where the first signal line V1, the second signal line V2, and the fan-out line F2 are located is on a side of the film layer where the connection line F1 is located that is close to the substrate 105, the connection line F1 is farther from the substrate 105, which can reduce the coupling capacitance of the connection line F1 with other film layers on the substrate 105, so that the signal transmitted on the connection line F1 is more accurate.

It should be noted that FIGS. 18 and 19 illustrate the situation where the film layer where the first signal line V1, the second signal line V2, and the fan-out line F2 are located is on a side of the film layer where the connection line F1 is located that is remote from the substrate 105. However, this is not intended to be limiting.

The technical solution of this embodiment allows the connection line F1 to be disposed on a different layer from the second initialization signal line 106. This can enable the use of a material with lower resistivity for the connection lines F1, and can also increase the distance between the first signal line V1 and the substrate 105, which helps to improve the accuracy of signal transmission on the connection lines F1 and the first signal lines V1. Alternatively, the connection line F1 and the second initialization signal line 106 can be disposed in the same layer, thereby reducing the number of film layers and simplifying the manufacturing process.

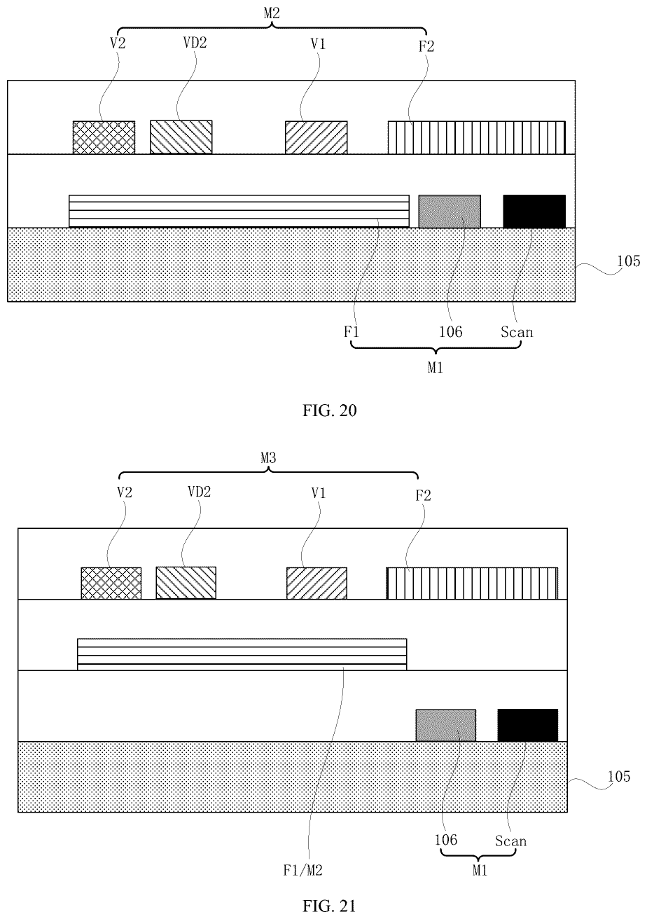

On the basis of the above technical solution, FIG. 20 is a sectional view of FIG. 17 taken along line c1-c2. Optionally, with reference to FIG. 20, the display panel further includes a substrate 105, a plurality of scan lines Scan and a plurality of second initialization signal lines 106 extending along the second direction Y, the second initialization signal line 106 being connected to the second signal line V2. The display panel further includes a first conductive layer M1 and a second conductive layer M2 that are located on the substrate 105, where the scan line Scan, the second initialization signal line 106, and the connection line F1 are located in the first conductive layer M1, and the first signal line V1, the fan-out line F2, and the second signal line V2 are located in the second conductive layer M2.

The first conductive layer M1 is located on the substrate 105, and the second conductive layer M2 is located on a side of the first conductive layer M1 that is remote from the substrate 105. Alternatively, the second conductive layer M2 is located on the substrate 105, and the first conductive layer M1 is located on a side of the second conductive layer M2 that is remote from the substrate 105. FIG. 16 illustrates the situation where the first conductive layer M1 is located on the substrate 105, and the second conductive layer M2 is located on a side of the first conductive layer M1 that is remote from the substrate 105. However, this is not intended to be limiting. The plurality of scan lines Scan may include the first scan line S1 and the second scan line S2 as described above, and may also include the light-emission control line EM as described above. As shown in FIG. 16, the above second traces VD2 are also located in the second conductive layer M2. That is, the power line group VDD is located in the second conductive layer M2. The scan lines Scan may extend along the second direction Y. Optionally, the various signal lines extend along the corresponding directions in the form of one or more of a straight line, a curved line, and a polyline.

In particular, the scan line Scan, the second initialization signal line 106, and the connection line F1 are located in the first conductive layer M1. The first conductive layer M1 may be a titanium-aluminum-titanium stack, or it may be a molybdenum conductive layer. The first signal line V1, the fan-out line F2, and the second signal line V2 are located in the second conductive layer M2. The second conductive layer M2 may be a titanium-aluminum-titanium stack. In this way, the number of layers of conductive layers can be reduced, which is beneficial for simplifying the manufacturing process and reducing costs. Furthermore, the resistivity of the materials of the first signal lines V1, the fan-out lines F2, and the second signal lines V2 is relatively low, which can reduce the value of resistance and consequently reduce the voltage loss, thereby helping to improve the accuracy in signal transmission on the first signal lines V1, the fan-out lines F2, and the second signal lines V2. An insulating layer can be disposed between the conductive layers.

Optionally, with reference to FIGS. 17 and 20, the scan lines Scan and the connection lines F1 are spaced apart from each other; and in the first direction X, a distance between the scan line Scan and the connection line F1 is greater than a preset spacing. In this way, the coupling capacitance between the scan line Scan and the connection line F1 can be eliminated. The signals transmitted on the scan line Scan are varying signals, which include high levels and low levels. Therefore, this can prevent fluctuations in the signals on the connection line F1 caused by the varying signals transmitted on the scan line Scan. This facilitates improving the accuracy of signal transmission on the connection line F1.

Optionally, with reference to FIGS. 17 and 20, in the first direction X, the second initialization signal line 106 is located between the scan line Scan and the connection line F1.

In particular, the signal transmitted on the second initialization signal line 106 is a signal of fixed potential. By arranging the second initialization signal line 106 between the scan line Scan and the connection line F1, the effects of isolation and shielding can be achieved, which further prevents fluctuations in the signals on the connection line F1 caused by the varying signals transmitted on the scan line Scan, thereby further improving the accuracy of signal transmission on the connection line F1.

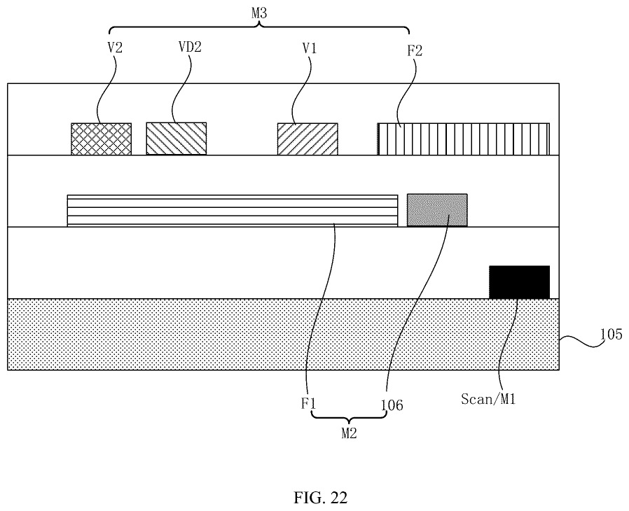

In another implementation, FIG. 21 is a further sectional view of FIG. 17 taken along line c1-c2, and FIG. 22 is a further sectional view of FIG. 17 taken along line c1-c2. Optionally, with reference to FIGS. 21 and 22, the display panel further includes a substrate 105, a plurality of scan lines Scan and a plurality of second initialization signal lines 106 extending along the second direction Y, the second initialization signal line 106 being connected to the second signal line V2.

The display panel further includes a first conductive layer M1, a second conductive layer M2, and a third conductive layer M3 that are located on the substrate 105, where the scan line Scan is located in the first conductive layer M1 and the connection line F1 is located in the second conductive layer M2; and the first signal line V1, the fan-out line F2, and the second signal line V2 are located in the third conductive layer M3.

The first conductive layer M1, the second conductive layer M2, and the third conductive layer M3 may be disposed in a stacked manner, for example, sequentially disposed in a stacked manner along a direction away from the substrate. The first conductive layer M1 is located on a side of the substrate 105, the second conductive layer M2 is located on a side of the first conductive layer M1 that is remote from the substrate 105, and the third conductive layer M3 is located on a side of the second conductive layer M2 that is remote from the substrate 105. As shown in FIGS. 21 and 22, the above second traces VD2 are also located in the third conductive layer M3. That is, the power line group VDD is located in the third conductive layer M3.

Specifically, the scan line Scan is located in the first conductive layer M1, and the connection line F1 is located in the second conductive layer M2, so that the scan line Scan and the connection line F1 are not in the same conductive layer. This can reduce the fluctuations in the signals on the connection line F1 caused by the varying signals transmitted on the scan line Scan, thereby improving the accuracy of signal transmission on the connection line F1. Furthermore, the first signal line V1, the fan-out line F2, and the second signal line V2 are located in the third conductive layer M3, making the first signal line V1, the fan-out line F2, and the second signal line V2 farther from the substrate 105. This reduces the coupling capacitance of the first signal line V1, the fan-out line F2, and the second signal line V2 with other film layers on the substrate 105, so that the signals transmitted on the first signal line V1, the fan-out line F2, and the second signal line V2 are more accurate.

In an implementation, optionally, with reference to FIG. 21, the second initialization signal line 106 is located in the first conductive layer M1. In this way, the connection line F1 can be arranged separately in an individual second conductive layer M2, which allows the material of the connection line F1 to differ from that of the second initialization signal line 106. For example, the resistivity of the material of the connection line F1 can be set to be lower than that of the material of the second initialization signal line 106. This helps to reduce the value of resistance of the connection line F1, thereby reducing the voltage drop on the connection line F1. As a result, the voltage loss during transmission on the connection line F1 is reduced, thereby enhancing the accuracy of signal transmission.

In another implementation, optionally, with reference to FIG. 22, the second initialization signal line 106 is located in the second conductive layer M2. In this way, the material of the second initialization signal line 106 may also be one with lower resistivity, which helps to reduce the value of resistance of the second initialization signal line 106, thereby reducing the voltage loss on the second initialization signal line 106 and improving the accuracy of the transmission of initialization signals.

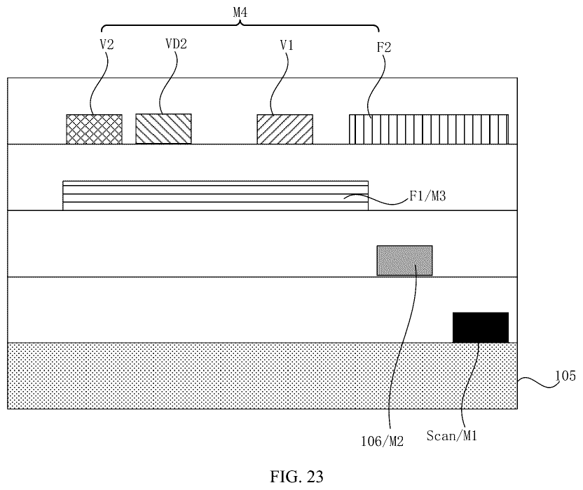

In a further implementation, FIG. 23 is a further sectional view of FIG. 17 taken along line c1-c2. Optionally, with reference to FIG. 23, the display panel further includes a first conductive layer M1, a second conductive layer M2, a third conductive layer M3, and a fourth conductive layer M4 that are located on the substrate 105, where the scan line Scan is located in the first conductive layer M1; the second initialization signal line 106 is located in the second conductive layer M2; the connection line F1 is located in the third conductive layer M3; and the first signal line V1, the fan-out line F2, and the second signal line V2 are located in the fourth conductive layer M4. In this way, the connection line F1 is located separately in a conductive layer, the materials of the connection line F1, the first signal line V1, the fan-out line F2, and the second signal line V2 may be those with lower resistivity, for example, a titanium-aluminum-titanium stack, thereby reducing the value of resistance of the connection line F1, the first signal line V1, the fan-out line F2, and the second signal line V2. This helps to reduce the voltage loss and improve the accuracy of signal transmission. The scan line Scan and the second initialization signal line 106 can be made of materials with slightly higher resistivity, for example, a molybdenum metal, which can reduce costs. Furthermore, the first signal line V1, the fan-out line F2, and the second signal line V2 are located far from the scan line Scan, and the connection line F1 is also located far from the scan line Scan. This can reduce the impact of signal fluctuations on the scan line Scan on the voltage transmitted on the connection line F1, the first signal line V1, the fan-out line F2, and the second signal line V2, thereby further improving the accuracy of signal transmission.

In the technical solution of this embodiment, by disposing the connection line F1, the second initialization signal line 106, and the scan line Scan on the same film layer, the number of film layers can be reduced to a large extent. By positioning the connection line F1 and the second initialization signal line 106 in the second conductive layer M2, and the scan line Scan in the first conductive layer M1, the degree of interference from the scan line Scan on the fan-out line F2 and the first signal line V1 can be reduced, thereby improving the accuracy of signal transmission. By positioning the scan line Scan in the first conductive layer M1, the second initialization signal line 106 in the second conductive layer M2, the connection line F1 in the third conductive layer M3, and the first signal line V1, the fan-out line F2, and the second signal line V2 in the fourth conductive layer M4, the materials of the connection line F1, the first signal line V1, the fan-out line F2, and the second signal line V2 can be those with lower resistivity, and the distances from the first signal line V1, the fan-out line F2, and the second signal line V2 to the scan line Scan can be further increased, which helps to further improve the accuracy of signal transmission.

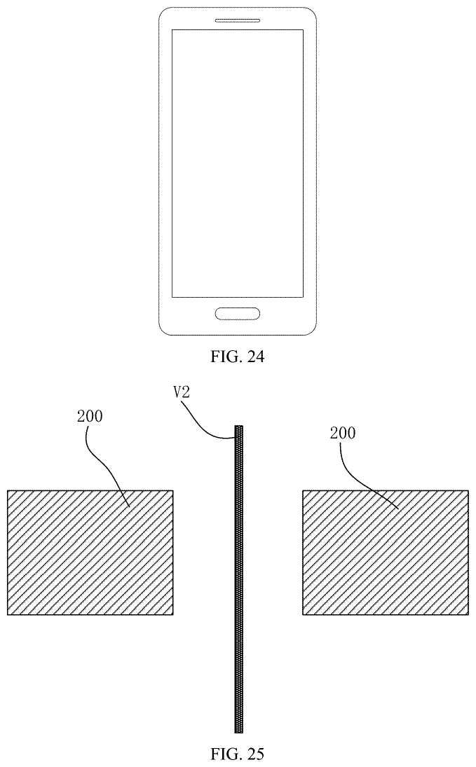

The present disclosure further provides a display module, including the display panel according to any one of the implementations described above. FIG. 24 is a schematic diagram of a structure of a display module according to an embodiment of the present disclosure. The display module in the embodiments of the present disclosure may include one or more of a polarizer, a touch layer, a cover plate, and other structures. The polarizer is disposed between the touch layer and the display panel, and the cover plate is disposed on a side of the touch layer that faces away from the display panel. The display module can be applied to a mobile phone, a tablet, a display, a smart watch, an MP3, an MP4, or other wearable devices, and so on. As it incorporates the display panel according to any embodiment of the present disclosure, it also possesses the same beneficial effects, which will not be repeated here.

The present disclosure further provides a display device, including the display module according to any of the above implementations. Therefore, it possesses the same beneficial effects as the display module according to any of the above implementations, which will not be repeated here. This display device may be a mobile phone, a tablet, a display, a smart watch, an MP3, an MP4 or other wearable apparatuses.

The above detailed description does not constitute a limitation on the scope of protection of the present disclosure. It should be understood by those skilled in the art that various modifications, combinations, sub-combinations, and substitutions can be made based on design requirements and other factors. Any modifications, equivalent substitutions, or improvements made within the spirit and principle of the present disclosure should be included within the scope of protection of the present disclosure.

What is claimed is:

1. A display panel, comprising a display area and a non-display area, and the display panel comprising:
a plurality of first signal lines, the first signal line extending along a first direction;
a plurality of connection lines, the connection line being connected to the first signal line, and the connection line being located in the display area;
a plurality of fan-out lines, at least a part of the fan-out line extending along the first direction and being connected to the connection line, and the fan-out line extending from the non-display area to the display area; and
a plurality of second signal lines, the second signal line extending along the first direction;
wherein the first signal line, the second signal line, and the fan-out line are disposed in the same layer and distributed along a second direction intersecting with the first direction.

2. The display panel according to claim 1, further comprising a plurality of power line groups, the power line group being disposed in the same layer as the first signal line, wherein the power line group comprises a first trace and a second trace, the first trace, the second trace, and the first signal line are disposed in the same layer, the display panel further comprises a plurality of pixel circuits, and the first trace and the second trace are respectively connected to the different pixel circuits.

3. The display panel according to claim 2, wherein at least one of the second signal lines or at least one of the fan-out lines is disposed between the first trace and the second trace in the same power line group.

4. The display panel according to claim 3, wherein one of the second signal lines or one of the fan-out lines is disposed between the first trace and the second trace in the same power line group, with the first trace and the second trace being symmetrical with respect to the second signal line or the fan-out line.

5. The display panel according to claim 3, wherein at least one of the second signal lines is disposed between two adjacent ones of the fan-out lines; and
one of the first signal lines is disposed between the adjacent fan-out line and second signal line.

6. The display panel according to claim 5, wherein the plurality of first signal lines form a plurality of first signal line groups, the first signal line group comprises two first signal lines disposed between two adjacent ones of the power line groups, and at least one of the second signal lines or at least one of the fan-out lines is disposed between the two first signal lines in the first signal line group.

7. The display panel according to claim 6, wherein the first signal line groups and the power line groups are alternately arranged along the second direction.

8. The display panel according to claim 7, wherein one of the adjacent fan-out line and second signal line is located between the two first signal lines in the first signal line group, and the other one of the adjacent fan-out line and second signal line is located between the first trace and the second trace in the power line group.

9. The display panel according to claim 5, wherein one first trace or one second trace is disposed between the adjacent fan-out line and second signal line.

10. The display panel according to claim 1, wherein the display panel further comprises a plurality of pixel circuits, the first signal line is a data line configured to transmit a data voltage to the pixel circuit; and the second signal line is a first initialization signal line configured to transmit an initialization voltage to the pixel circuit.

11. The display panel according to claim 1, wherein the display panel further comprises a plurality of pixel circuits, two adjacent pixel circuits of the plurality of pixel circuits are arranged along a row direction and have active layers symmetrical with respect to the second signal line; or two adjacent pixel circuits of the plurality of pixel circuits are arranged along a row direction and have active layers symmetrical with respect to the fan-out line, with the row direction being parallel to the second direction.

12. The display panel according to claim 11, wherein among three pixel circuits arranged sequentially along the row direction, an active layer of a pixel circuit in a middle position and an active layer of a pixel circuit on one side are symmetrical with respect to the second signal line, and the active layer of the pixel circuit in the middle position and an active layer of a pixel circuit on the other side are symmetrical with respect to the fan-out line.

13. The display panel according to claim 1, wherein the display panel further comprises a plurality of light-emitting elements and a plurality of pixel circuits, and the pixel circuit comprises a driving transistor;
the second signal line comprises a first initialization sub-line, wherein the first initialization sub-line is configured to provide an initialization signal to a first electrode of the light-emitting element or a gate of the driving transistor; or
the plurality of second signal lines comprise a plurality of first initialization sub-lines and a plurality of second initialization sub-lines, wherein the first initialization sub-line is configured to provide an initialization signal to a first electrode of the light-emitting element, and the second initialization sub-line is configured to provide an initialization signal to a gate of the driving transistor; or
the plurality of second signal lines comprise a plurality of first initialization sub-lines, a plurality of second initialization sub-lines, and a plurality of third initialization sub-lines, wherein the first initialization sub-line is configured to provide an initialization signal to a first electrode of the light-emitting element, the second initialization sub-line is configured to provide an initialization signal to a gate of the driving transistor, and the third initialization sub-line is configured to provide an initialization signal to a source or a drain of the driving transistor.

14. The display panel according to claim 13, wherein the plurality of second signal lines comprise the plurality of first initialization sub-lines and the plurality of second initialization sub-lines, one first initialization sub-line or one second initialization sub-line is disposed between two adjacent ones of the fan-out lines; or the first initialization sub-line, the second initialization sub-line, and the fan-out line are arranged sequentially along the second direction.

15. The display panel according to claim 13, wherein the plurality of second signal lines comprise the plurality of first initialization sub-lines, the plurality of second initialization sub-lines, and the plurality of third initialization sub-lines, one first initialization sub-line or one second initialization sub-line or one third initialization sub-line is disposed between two adjacent ones of the fan-out lines; or the first initialization sub-line, the second initialization sub-line, the third initialization sub-line, and the fan-out line are arranged sequentially along the second direction.

16. The display panel according to claim 1, wherein the second signal line is a first initialization signal line, the display panel further comprises a substrate and a plurality of second initialization signal lines extending along the second direction, and the second initialization signal line is connected to the second signal line;
the second initialization signal line and the connection line are disposed in the same layer, or a film layer where the second initialization signal line is located is on a side of a film layer where the connection line is located facing the substrate; and
a film layer where the first signal line, the second signal line, and the fan-out line are located is on a side of the film layer where the connection line is located facing or facing away from the substrate.

17. The display panel according to claim 1, wherein the second signal line is a first initialization signal line, the display panel further comprises a substrate, a plurality of scan lines, and a plurality of second initialization signal lines extending along the second direction, and the second initialization signal line is connected to the second signal line; and
the display panel further comprises a first conductive layer and a second conductive layer located on the substrate, the scan line, the second initialization signal line, and the connection line are located in the first conductive layer, and the first signal line, the fan-out line, and the second signal line are located in the second conductive layer.

18. The display panel according to claim 17, wherein the scan line and the connection line are spaced apart from each other; and
along the first direction, the second initialization signal line is located between the scan line and the connection line.

19. The display panel according to claim 1, wherein the second signal line is a first initialization signal line, the display panel further comprises a substrate, a plurality of scan lines, and a plurality of second initialization signal lines extending along the second direction, and the second initialization signal line is connected to the second signal line;
the display panel further comprises a first conductive layer, a second conductive layer, and a third conductive layer that are located on the substrate, the scan line is located in the first conductive layer, and the connection line is located in the second conductive layer; the first signal line, the fan-out line, and the second signal line are located in the third conductive layer; and the second initialization signal line is located in the first conductive layer or the second conductive layer; or
the display panel further comprises a first conductive layer, a second conductive layer, a third conductive layer, and a fourth conductive layer that are located on the substrate, the scan line is located in the first conductive layer; the second initialization signal line is located in the second conductive layer; the connection line is located in the third conductive layer; and the first signal line, the fan-out line, and the second signal line are located in the fourth conductive layer.

20. A display device, comprising the display panel according to claim 1.
